(19) United States
(12) Patent Application Publication
(10) Pub. No.: US 2015/0004733 A1
(43) Pub. Date: Jan. 1, 2015

(54) EXFOLIATION OF THERMOELECTRIC MATERIALS AND TRANSITION METAL DICHALCOGENIDES USING IONIC LIQUIDS

(71) Applicant: The Board of Trustees of The University Of Alabama, Tuscaloosa, AL (US)

(72) Inventors: Hung-Ta Wang, Tuscaloosa, AL (US); Rachel M. Frazier, Tuscaloosa, AL (US); Lingling Guo, Tuscaloosa, AL (US); Haiyu Quan, Tuscaloosa, AL (US); Parker D. McCrary, Tuscaloosa, AL (US); Robin D. Rogers, Tuscaloosa, AL (US)

(21) Appl. No.: 14/317,614

(22) Filed: Jun. 27, 2014

Related U.S. Application Data
(60) Provisional application No. 61/839,896, filed on Jun. 27, 2013.

(51) Int. Cl. H01L 35/34; C09D 11/52; C09D 11/03; C01B 19/04

(52) U.S. Cl. CPC H01L 35/34; C01B 19/04; C09D 11/52; C09D 11/03
USPC 438/54; 423/509; 252/62.3 T

(57) ABSTRACT

Disclosed are methods of exfoliating a thermoelectric material, such as bismuth telluride or antimony telluride, using one or more ionic liquids. Also disclosed is the exfoliated thermoelectric material provided by the disclosed methods. Further disclosed are compositions comprising the exfoliated thermoelectric material and methods of making and using the compositions. Additionally disclosed are exfoliated transition metal dichalcogenide compositions, methods of making and using such compositions.

### CROSS-REFERENCE TO RELATED APPLICATIONS

This application claims the benefit of priority to U.S. Provisional Application No. 61/839,896, filed Jun. 27, 2013, which is hereby incorporated herein by reference in its entirety.

### FIELD

The subject matter disclosed herein generally relates to reliable and effective methods for producing two dimensional (2D) or quasi 2D materials, including thermoelectric materials and transition metal dichalcogenides. More specifically, the subject matter disclosed herein generally relates to methods for the exfoliation of thermoelectric materials or transition metal dichalcogenides using ionic liquids. The disclosed subject matter also relates to compositions comprising the exfoliated thermoelectric materials or transition metal dichalcogenides and methods of using same.

### BACKGROUND

Approximately 90% of the world's electricity is generated by heat energy, typically operating at 30-40% efficiency, losing roughly 15 terawatts of power in the form of heat to the environment. Thermoelectric (TE) devices could convert some of this waste heat into useful electricity.

For example, thermoelectric generators are electronic devices that convert heat into electricity by placing devices in parallel to a temperature gradient, or having thermoelectric effect. The thermoelectric effect refers to phenomena by which either a temperature difference creates an electric potential or an electric potential creates a temperature difference. These phenomena are known more specifically as the Seebeck effect (converting a temperature gradient to an electrical current), Peltier effect (converting an electrical current to a temperature gradient), and Thomson effect (conductor heating/cooling). While all materials have a nonzero thermoelectric efficiency (converting heat energy to electricity), in most materials it is too small to be useful. However, commercial thermoelectric materials that have a relatively strong thermoelectric effect (and other required properties, such as a high Seebeck coefficient, a high electrical conductivity, and a low thermal conductivity) could be used in applications including power generation and refrigeration.

A commonly used thermoelectric material in such applications is bismuth telluride (Bi₂Te₃). Bismuth telluride and its alloys are unique thermoelectric materials that are as important to the thermoelectric industry—for cooling and energy generation applications—as silicon is important to the electronic industry. Bismuth telluride (Bi₂Te₃) has a hexagonal crystal (also a known as a rhombohedral crystal structure), and typically forms layered flakes or platelets with a metallic luster or black powder. It is an alloy of two metallic elements (bismuth and tellurium) also known as bismuth (III) telluride. It is a semiconductor that alone or when alloyed with antimony or selenium is an efficient thermoelectric material for refrigeration or portable power generation. Topologically protected surface states (also known as topological surface states) have also been observed in bismuth telluride and its family alloys.

Solid-state thermoelectric generators/refrigerators are compact, scalable, quiet, and emit zero carbon. They are suitable for multiple energy applications, such as conversion of battlefield waste heat (from engines, weapons, campfires, human bodies, etc.) into electricity, integration with photovoltaics to become thermo-photovoltaics, as well as on-chip cooling for wide bandgap power electronics, or IR detectors as discussed in L. E. Bell, “Cooling, heating, generating power, and recovering waste heat with thermoelectric systems,” Science, vol. 321, pp. 1457.1461, 2008. For example, internal combustion engines capture only 20-25% of the energy released during fuel combustion, but the other 75-80% of the fuel is wasted as heat. Increasing the energy conversion rate can increase mileage and provide more electricity for on-board controls and comforts (such as in stability controls, telematics, navigation systems, electronic braking, etc.). It may be possible to shift energy drawn from the engine (in certain cases, such as accelerating) to the electrical load in the car, e.g. electrical power steering or electrical coolant pump operation. Cogeneration power plants use the heat produced during electricity generation for alternative purposes. Thermoelectrics may find applications in such systems or in solar thermal energy generation. On the other hand, the main advantages of a thermoelectric cooler (also known as Peltier coolers) compared to a vapor-compression refrigerator are its lack of moving parts or circulating fluid, and its small size and flexible shape (form factor). Another advantage is that Peltier coolers do not require refrigerant fluids, such as chlorofluorocarbons (CFCs) and related chemicals, which can have harmful environmental effects.

In addition to thermoelectrics, spintronics is a new and promising technology in which the intrinsic spin of electrons, rather than the value of a voltage like in today's electronics, is used to store and transport information to be interpreted as either a “1” or a “0”. The materials most apt to use in the field of spintronics are what experts call topological insulators, the new quantum matters (known as topological surface states) that scientists have been searching for years and have now finally found in bismuth telluride. Without a magnetic field, bismuth telluride allows spin carriers on its surface to travel with no loss of energy at room temperatures and can be fabricated using existing semiconductor technologies. Such material could provide a leap in microchip speeds, reduce microchip power consumptions, and even become the bedrock of an entirely new kind of computing industry based on spintronics, the next evolution of electronics.

Two main challenges toward these practical applications are the lack of qualified thermoelectric materials able to efficiently manipulate low quality heat (T<200° C., which is difficult to be captured), and the lack of practical techniques to make versatile thermoelectric devices.

Thus, there exists a need for methods and compositions that overcome some of problems in the state-of-the-art of fabricating qualified thermoelectric materials such as bismuth telluride, bismuth selenide (Bi₂Se₃), and/or antimony telluride (Sb₂Te₃), or transition metal dichalcogenides, a few of which are aforementioned. Disclosed herein are compositions and methods that meet these and other needs.

### SUMMARY

In accordance with the purposes of the disclosed materials, compounds, compositions, articles, devices, and methods, as embodied and broadly described herein, the disclosed subject matter, in one aspect, relates to compositions and methods for preparing compositions and using them. Further, the subject matter disclosed herein relates to exfoliated thermoelectric materials and exfoliated transition metal dichalcogenides, and methods of obtaining and using them. In an additional aspect, the disclosed subject matter relates to compositions of exfoliated thermoelectric materials or exfoliated transition metal dichalcogenides in an ionic liquid, and methods of obtaining and using them. In a further aspect, the disclosed subject matter relates to compositions comprising exfoliated thermoelectric materials or exfoliated transition metal dichalcogenides, and the use of said compositions as printable/writable inks. In a further aspect, the disclosed subject matter relates to the use of one or more ionic liquids in combination with a disclosed method, composition, composite, and the like.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### BRIEF DESCRIPTION OF THE FIGURES

The accompanying figures, which are incorporated in and constitute a part of this specification, illustrate several aspects described below.

FIG. 1 is a schematic diagram illustrating the formation of two-dimensional material from stacks of two-dimensional plates.

FIG. 2 is a crystal structure of Bi₂Te₃ showing a quintuple sheet, a van der Waals gap, and a rhombohedral unit cell.

FIG. 3A is a schematic diagram showing nanoplatelets being exfoliated into quintuple sheets.

FIG. 3B is a schematic diagram showing the methods of forming a printable ink using a Bi₂Te₃ quintuple sheet dispersion in an ionic liquid.

FIG. 4 is a scanning electron microscopy (SEM) micrograph of synthesized nanoplatelets of Bi₂Te₃ used as the raw material for the ionic liquid exfoliation.

FIG. 5A is a photograph showing the Bi₂Te₃ nanoplatelets in an ionic liquid before and after the exfoliation.

FIG. 5B is a transmission electron microscopy (TEM) image indicating that the Bi₂Te₃ has been exfoliated.

FIGS. 6A-6C are atomic force microscopy (AFM) images of the three randomly-selected exfoliated bismuth telluride nanosheets.

FIG. 7A is the UV-vis spectra of reaction solutions at different stages or times of exfoliation.

FIG. 7B is the UV-vis spectra of exfoliated bismuth telluride at different settling times.

FIG. 8A is an SEM image of the ground bismuth telluride commercial powder.

FIG. 8B is a photograph of the solvothermal exfoliation setup.

FIG. 8C is an X-ray diffraction (XRD) spectra of exfoliated bismuth telluride commercial powder.

FIG. 8D is the low angle (2 theta<10 degree) XRD spectra of exfoliated bismuth telluride commercial powder.

### DETAILED DESCRIPTION

The materials, compounds, compositions, articles, devices, and methods described herein may be understood more readily by reference to the following detailed description of specific aspects of the disclosed subject matter and the Examples included therein and to the Figures.

Before the present materials, compounds, compositions, articles, devices, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### GENERAL DEFINITIONS

In this specification and in the claims that follow, reference will be made to a number of terms, which shall be defined to have the following meanings:

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not. For example, the phrase “X is an optional component in the ionic liquid” means that X may or may not be present in the ionic liquid and that the description includes both ionic liquids where X is present and where X is not present.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. “About” is used to mean within 5% of the stated value, e.g., within 2 or 1% of the stated value.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

### CHEMICAL DEFINITIONS

As used herein, the term “quintuple sheet (QS)” is meant to refer to stack of five alternating atomic layers or sheets. In one aspect, exfoliated bismuth telluride described herein includes 5 atomic layers or sheets of tellurium-bismuth-tellurium-bismuth-tellurium. The terms “exfoliated bismuth telluride” is contemplated to include 5 atomic sheets of bismuth telluride, i.e., bismuth telluride quintuple sheets or bismuth telluride QS (of which the thickness is, for example, about 1 nm), as well as a stack of a few quintuple sheets (of which the thickness is, for example, less than 20 nm). The term “exfoliate” as used herein, refers to a disruption of the van der Waals force between the quintuple sheets of the bismuth telluride. The term “bismuth telluride” is meant to include commercially available macro-sized bismuth telluride powder (i.e., μm sized flakes), synthesized bismuth telluride, and in some aspects, bismuth telluride nanoparticles or nanoplatelets.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valencies of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc.

“A¹,” “A²,” “A³,” and “A⁴” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, such as methyl, ethyl, n-propyl, isopropyl, n-butyl, isobutyl, t-butyl, pentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “alkoxy” as used herein is an alkyl group bound through a single, terminal ether linkage; that is, an “alkoxy” group can be defined as —OA¹ where A¹ is alkyl as defined above.

The term alkoxylalkyl as used herein is an alkyl group that contains an alkoxy substituent and can be defined as -A¹-O-A², where A¹ and A² are alkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This may be presumed in structural formulae herein wherein an asymmetric alkene is present, or it may be explicitly indicated by the bond symbol C═C. The alkenyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

The term “alkynyl” as used herein is a hydrocarbon group of 2 to 24 carbon atoms with a structural formula containing at least one carbon-carbon triple bond. The alkynyl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol, as described below.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, halogenated alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein. The term “biaryl” is a specific type of aryl group and is included in the definition of aryl. Biaryl refers to two aryl groups that are bound together via a fused ring structure, as in naphthalene, or are attached via one or more carbon-carbon bonds, as in biphenyl.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, etc. The term “heterocycloalkyl” is a cycloalkyl group as defined above where at least one of the carbon atoms of the ring is substituted with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein.

The term “cycloalkenyl” as used herein is a non-aromatic carbon-based ring composed of at least three carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like. The term “heterocycloalkenyl” is a type of cycloalkenyl group as defined above, and is included within the meaning of the term “cycloalkenyl,” where at least one of the carbon atoms of the ring is substituted with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, alkoxy, alkenyl, alkynyl, aryl, heteroaryl, aldehyde, amino, carboxylic acid, ester, ether, halide, hydroxy, ketone, nitro, silyl, sulfo-oxo, sulfonyl, sulfone, sulfoxide, or thiol as described herein.

The term “cyclic group” is used herein to refer to either aryl groups, non-aryl groups (i.e., cycloalkyl, heterocycloalkyl, cycloalkenyl, and heterocycloalkenyl groups), or both. Cyclic groups have one or more ring systems that can be substituted or unsubstituted. A cyclic group can contain one or more aryl groups, one or more non-aryl groups, or one or more aryl groups and one or more non-aryl groups.

The term “aldehyde” as used herein is represented by the formula —C(O)H. Throughout this specification “C(O)” is a short hand notation for C═O.

The terms “amine” or “amino” as used herein are represented by the formula NA¹A²A³, where A¹, A², and A³ can be, independently, hydrogen, an alkyl, halogenated alkyl, alkenyl, alkynyl, aryl, heteroaryl, cycloalkyl, cycloalkenyl, heterocycloalkyl, or heterocycloalkenyl group described above.

The term “carboxylic acid” as used herein is represented by the formula —C(O)OH. A “carboxylate” as used herein is represented by the formula —C(O)O⁻.

The term “ester” as used herein is represented by the formula —OC(O)A¹ or —C(O)OA¹, where A¹ can be an alkyl, halogenated alkyl, alkenyl, alkynyl, aryl, heteroaryl, cycloalkyl, cycloalkenyl, heterocycloalkyl, or heterocycloalkenyl group described above.

The term “ether” as used herein is represented by the formula A¹OA², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “ketone” as used herein is represented by the formula A¹C(O)A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “halide” as used herein refers to the halogens fluorine, chlorine, bromine, and iodine.

The term “hydroxyl” as used herein is represented by the formula —OH.

The term “nitro” as used herein is represented by the formula —NO₂.

The term “silyl” as used herein is represented by the formula —SiA¹A²A³, where A¹, A², and A³ can be, independently, hydrogen, alkyl, halogenated alkyl, alkoxy, alkenyl, alkynyl, aryl, heteroaryl, cycloalkyl, cycloalkenyl, heterocycloalkyl, or heterocycloalkenyl group described above.

The term “sulfo-oxo” as used herein is represented by the formulas —S(O)A¹, —S(O)₂A¹, —OS(O)₂A¹, or —OS(O)₂OA¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group described above. Throughout this specification “S(O)” is a short hand notation for S═O

The term “sulfonyl” is used herein to refer to the sulfo-oxo group represented by the formula —S(O)₂A¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group described above.

The term “sulfonylamino” or “sulfonamide” as used herein is represented by the formula —S(O)₂NH—.

The term “sulfone” as used herein is represented by the formula A¹S(O)₂A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “sulfoxide” as used herein is represented by the formula A¹S(O)A², where A¹ and A² can be, independently, an alkyl, halogenated alkyl, alkenyl, alkynyl, aryl, heteroaryl, cycloalkyl, cycloalkenyl, heterocycloalkyl, or heterocycloalkenyl group described above.

The term “thiol” as used herein is represented by the formula —SH.

“R¹,” “R²,” “R³,” “Rⁿ,” where n is an integer, as used herein can, independently, possess one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

Unless stated to the contrary, a formula with chemical bonds shown only as solid lines and not as wedges or dashed lines contemplates each possible isomer, e.g., each enantiomer and diastereomer, and a mixture of isomers, such as a racemic or scalemic mixture.

References to “mim,” “Cₙ-mim,” and “bmim” are intended to refer to a methyl imidazolium compound, an alkyl methyl imidazolium compound, and a butyl methyl imidazolium compound respectively.

The term “ion,” as used herein, refers to any molecule, portion of a molecule, cluster of molecules, molecular complex, moiety, or atom that contains a charge (positive, negative, or both (e.g., zwitterions)) or that can be made to contain a charge. Methods for producing a charge in a molecule, portion of a molecule, cluster of molecules, molecular complex, moiety, or atom are disclosed herein and can be accomplished by methods known in the art, e.g., protonation, deprotonation, oxidation, reduction, alkylation, etc.

The term “anion” is a type of ion and is included within the meaning of the term “ion”. An “anion” is any molecule, portion of a molecule (e.g., zwitterion), cluster of molecules, molecular complex, moiety, or atom that contains a net negative charge or that can be made to contain a net negative charge. The term “anion precursor” is used herein to specifically refer to a molecule that can be converted to an anion via a chemical reaction (e.g., deprotonation).

The term “cation” is a type of ion and is included within the meaning of the term “ion”. A “cation” is any molecule, portion of a molecule (e.g., zwitterion), cluster of molecules, molecular complex, moiety, or atom, that contains a net positive charge or that can be made to contain a net positive charge. The term “cation precursor” is used herein to specifically refer to a molecule that can be converted to a cation via a chemical reaction (e.g., protonation or alkylation).

Reference will now be made in detail to specific aspects of the disclosed materials, compounds, compositions, articles, and methods, examples of which are illustrated in the accompanying Examples and Figures.

### Materials and Compositions

Certain materials, compounds, compositions, and components disclosed herein can be obtained commercially or readily synthesized using techniques generally known to those of skill in the art. For example, the starting materials and reagents used in preparing the disclosed compounds and compositions are either available from commercial suppliers such as Aldrich Chemical Co., (Milwaukee, Wis.), Acros Organics (Morris Plains, N.J.), Fisher Scientific (Pittsburgh, Pa.), or Sigma (St. Louis, Mo.) or can be prepared by methods known to those skilled in the art following procedures set forth in references such as Fieser and Fieser's Reagents for Organic Synthesis, Volumes 1-17 (John Wiley and Sons, 1991); Rodd's Chemistry of Carbon Compounds, Volumes 1-5 and Supplementals (Elsevier Science Publishers, 1989); Organic Reactions, Volumes 1-40 (John Wiley and Sons, 1991); March's Advanced Organic Chemistry, (John Wiley and Sons, 4th Edition); and Larock's Comprehensive Organic Transformations (VCH Publishers Inc., 1989). In general, the thermoelectric materials can be derived from a natural source or from a synthetic source. It should be appreciated that the disclosed methods can be independent of the size or nature of the starting thermoelectric material.

Also, disclosed herein are materials, compounds, compositions, and components that can be used for, can be used in conjunction with, can be used in preparation for, or are products of the disclosed methods and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. For example, if a composition is disclosed and a number of modifications that can be made to a number of components of the composition are discussed, each and every combination and permutation that are possible are specifically contemplated unless specifically indicated to the contrary. Thus, if a class of components A, B, and C are disclosed as well as a class of components D, E, and F and an example of a composition A-D is disclosed, then even if each is not individually recited, each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all aspects of this disclosure including, but not limited to, steps in methods of making and using the disclosed compositions. Thus, if there are a variety of additional steps that can be performed it is understood that each of these additional steps can be performed with any specific aspect or combination of aspects of the disclosed methods, and that each such combination is specifically contemplated and should be considered disclosed.

Disclosed herein are methods to exfoliate a thermoelectric material, such as bismuth telluride, or a transition metal dichalcogenide into two dimensional or quasi two dimensional materials, such as quintuple sheets. The methods disclosed herein use ionic liquids to treat the thermoelectric material or transition metal dichalcogenide to allow direct exfoliation of the thermoelectric material or transition metal dichalcogenide. The disclosed thermoelectric material- or transition metal dichalcogenide-ionic liquid compositions can be incorporated into many existing technologies. For example, the compositions and methods for use therewith can be used to provide printable inks or material useful in thermoelectric applications.

### Thermoelectric Material- or Transition Metal Dichalcogenide-Ionic Liquid (IL) Compositions

Disclosed herein are compositions that comprise a thermoelectric material or a transition metal dichalcogenide and at least one ionic liquid. Such compositions can be used in accordance with the disclosed methods to provide exfoliated thermoelectric materials or exfoliated transition metal dichalcogenides. In some examples, the thermoelectric material can comprise bismuth telluride. In some aspects, the bismuth telluride can be synthetic bismuth telluride, such as, for example, synthetic bismuth telluride commercial powder available from Sigma-Aldrich (St. Louis, Mo.).

In some aspects, the composition comprises from about 0.01% to about 10% of the thermoelectric material or the transition metal dichalcogenide by weight of the total composition. For example, the composition can comprise from about 0.01% to about 1%, or from 0.01% to about 0.5% of the thermoelectric material or the transition metal dichalcogenide by weight of the total composition.

The thermoelectric material disclosed herein can be compatible with a variety of ionic liquids. Ionic liquids of differing composition can affect the exfoliation conditions (such as reaction time, temperature), solubility limit, and particle size of the exfoliated bismuth telluride, bismuth selenide, antimony telluride, and other V-VI group chalcogenides, i.e., Bi₍₂₋ₓ₎SbₓTe_{(3-y)}Se_{y}, where 0≦x≦2, and 0≦y≦3.

Ionic Liquid (IL)

The ionic liquids that can be used herein comprise ionized species (i.e., any stoichiometric or non-stoichiometric ratio of cations and anions) and have an accessible liquid state, typically possessing a melting point below about 150° C. In some cases, the ionic liquids can be organic salts containing one or more cations, such as ammonium, imidazolium, or pyridinium ions, although many other types are known and disclosed herein paired with a particular anion. It should be noted that, in various aspects, multiple ionic liquids of varying ion composition and ratios can be used. In one aspect, the ionic liquid can be a surfactant or have surfactant like properties. In another aspect, the ionic liquid is not a surfactant.

Cations

In some examples, the cation of can comprise an alkyl or aromatic heterocyclic cation, a guanidinium cation, a quaternary ammonium cation, or quaternary phosphonium cation. In some examples, the cation can be cyclic, such as an azolium cation, a cyclic ammonium cation, or an imidazolium cation. In some examples, the cation can comprise a single heteroatom wherein a sufficient number of substituted or unsubstituted linear or branched alkyl units are attached to the heteroatom such that a positively charged species is formed. For example, the cation can comprise Cₙ alkyl-methylimidazolium [Cₙmim], where n is an integer of from 1 to 8. In some examples, the cation can comprise C₁₋₄ alkyl-methylimidazolium [C₁₋₄mim]. In some examples, the cation can comprise an allyl methylimidazolium ion, [Amim]. Other non-limiting examples of cationic units include imidazoles, pyrazoles, thiazoles, isothiazoles, azathiozoles, oxothiazoles, oxazines, oxazolines, oxazaboroles, dithiozoles, triazoles, selenozoles, oxahospholes, pyrroles, boroles, furans, thiophenes, phospholes, pentazoles, indoles, indolines, oxazoles, isothirazoles, tetrazoles, benzofurans, dibenzofurans, benzothiophenes, dibenzothoiphenes, thiadiazoles, pyrdines, pyrimidines, pyrazines, pyridazines, piperazines, piperidines, morpholines, pyrans, annolines, phthalazines, quinazolines, and quinoxalines.

The cation of an ionic liquid can be cyclic or acyclic and can, in various aspects, correspond in structure to any one or more of the formulae shown below:

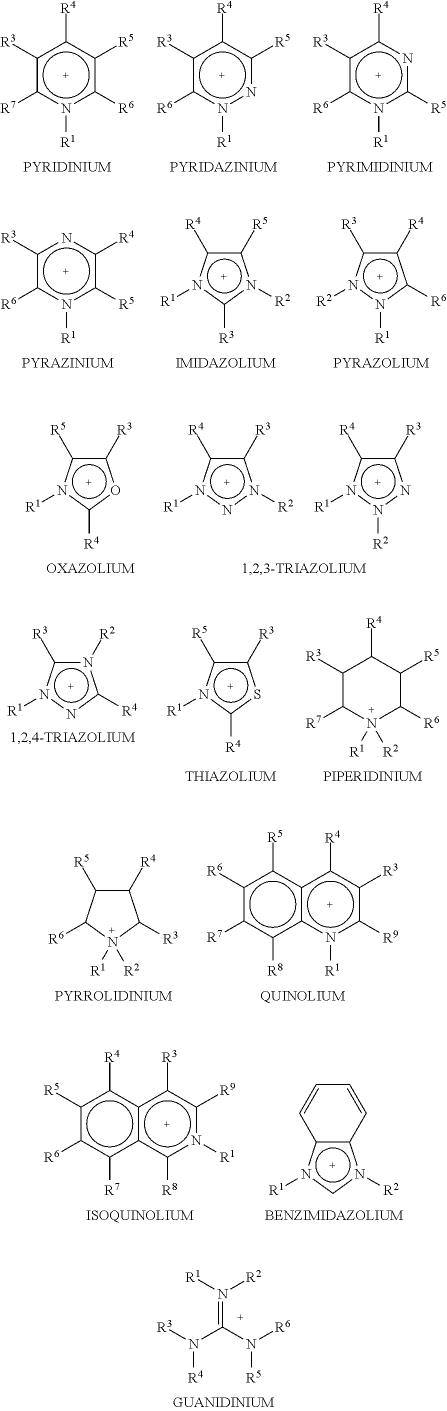

wherein R¹ and R² are independently a substituted or unsubstituted linear, branched, or cyclic C₁-C₆ alkyl group, a substituted or unsubstituted linear, branched, or cyclic C₁-C₆ alkoxy group, or a substituted or unsubstituted linear, branched, or cyclic C₁-C₆ alkoxyalkyl group, and R³, R⁴, R⁵, R⁶, R⁷, R⁸, and R⁹ (i.e., R³-R⁹), when present, are independently H, a substituted or unsubstituted linear, branched, or cyclic C₁-C₆ alkyl group, a substituted or unsubstituted linear, branched, or cyclic C₁-C₆ alkoxyalkyl group, or a substituted or unsubstituted linear, branched, or cyclic C₁-C₆ alkoxy group. In some examples, both R¹ and R² groups are C₁-C₄ alkyl, with one being methyl, and R³-R⁹, when present, are H. Exemplary C₁-C₆ alkyl groups and C₁-C₄ alkyl groups include methyl, ethyl, propyl, iso-propyl, butyl, sec-butyl, iso-butyl, pentyl, iso-pentyl, hexyl, 2-ethylbutyl, 2-methylpentyl, and the like. Corresponding C₁-C₆ alkoxy groups contain the above C₁-C₆ alkyl group bonded to an oxygen atom that is also bonded to the cation ring. An alkoxyalkyl group contains an ether group bonded to an alkyl group, and here contains a total of up to six carbon atoms. It is to be noted that there are two isomeric 1,2,3-triazoles. In some examples, all R groups not required for cation formation can be H. The phrase “when present” is often used herein in regard to substituent R group because not all cations have all of the numbered R groups. All of the contemplated cations contain at least four R groups, which can be H, although R² need not be present in all cations.

In some examples, all R groups that are not required for cation formation; i.e., those other than R¹ and R² for compounds other than the imidazolium, pyrazolium, and triazolium cations shown above, are H. Thus, the cations shown above can have a structure that corresponds to a structure shown below, wherein R¹ and R² are as described before.

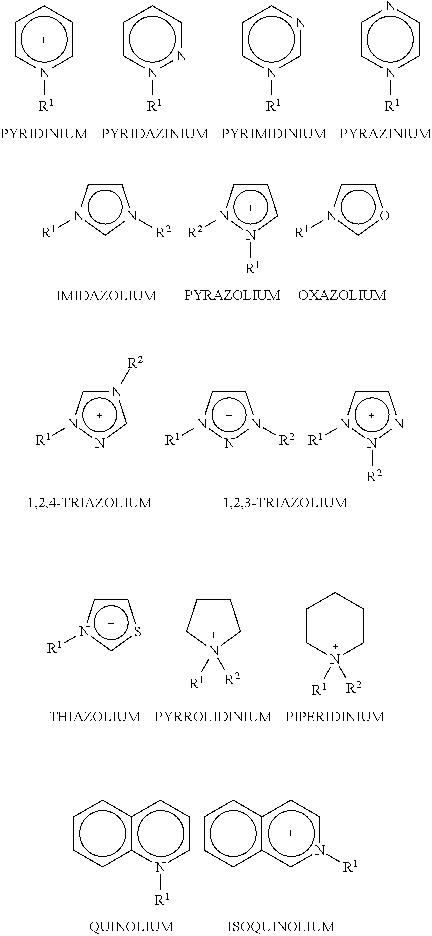

Exemplary cations are illustrated below wherein R¹, R², and R³-R⁵, when present, are as defined before.

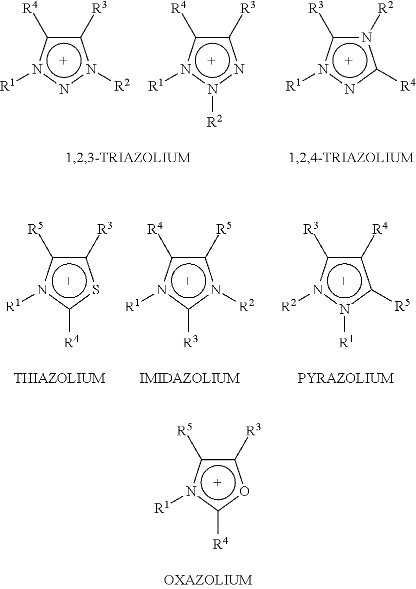

The following is a description of the short hand method used throughout the specification for referring to the imidazolium-based cations disclosed herein. The template:

[Cₙmim]

represents the cation portion wherein Cₙ represent an alkyl or substituted alkyl moiety having n number of carbon atoms. The term “mim” refers to “methyl substituted imidazolium.” Referring to the generic imidazolium formula:

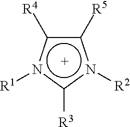

wherein R³, R⁴, and R⁵ are each hydrogen, can also be written as follows:

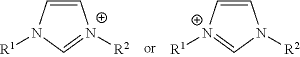

wherein either nitrogen can be depicted as having a positive charge. By the convention used herein the methyl group of “mim” refers to the R¹ moiety and the Cₙ substituent is the R² moiety. Therefore [C₂mim] represents a cation having the formula:

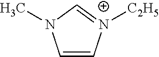

which can be equally well represented by the formula:

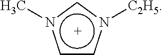

Of the cations that contain a single five-membered ring free of fusion to other ring structures, an imidazolium cation that corresponds in structure to Formula A is also suitable, wherein R¹, R², and R³-R⁵, are as defined before.

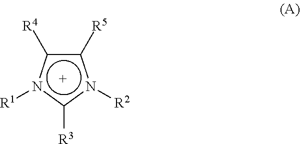

In some examples, an N,N-1,3-di-(C₁-C₁₆ alkyl)-substituted-imidazolium ion can be used; i.e., an imidazolium cation wherein R³-R⁵ of Formula A are each H, and R¹ and R² are independently each a C₁-C₁₆ alkyl group or a C₁-C₁₆ alkoxyalkyl group. In some examples, a 1-(C₁-C₁₆-alkyl)-3-(methyl)-imidazolium [Cₙ-mim, where n=1-16] cation and a halogen anion can be used. In some examples of Formula A, R³-R⁵ are each hydrogen, R² is methyl, R¹ is a C₁-C₁₆-alkyl group or a C₁-C₁₆ alkoxyalkyl group, and the cation can comprise a compound of Formula B.

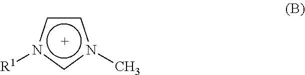

In some examples, the cation can comprise an ammonium cation, as shown in the formula below:

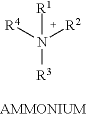

wherein R¹, R², R³, and R⁴, when present, are independently a C₁-C₁₈ alkyl group or a C₁-C₁₈ alkoxyalkyl group.

In some examples, the cation can comprise a phosphonium cation, such as shown in the formula below:

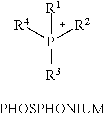

wherein R¹, R², R³, and R⁴, when present, are independently a C₁-C₁₈ alkyl group or a C₁-C₁₈ alkoxyalkyl group.

Some additional examples of ionic liquids include, but are not limited to, the following quaternary ammonium salts: Bu₄NOH, Bu₄N(H₂PO₄), Me₄NOH, Me₄NCl, Et₄NPF₆, and Et₄NCl.

The contemplated ionic liquid-solvent can also comprise mixtures of two, or more, of the contemplated ions or ionic liquids.

Anions

In some examples, the anion in the disclosed ionic liquid can comprise a halogen (fluoride, chloride, bromide, or iodide), perchlorate, pseudohalogen (such as, thiocyanate and cyanate), or C₁-C₆ carboxylate. Pseudohalides are monovalent and have properties similar to those of halides (Schriver et al., Inorganic Chemistry, W. H. Freeman & Co., New York, 1990, 406-407). Pseudohalides include the cyanide (CN), thiocyanate (SCN), cyanate (OCN⁻), fulminate (CNO⁻), dicyanamide (N(CN)₂⁻), and azide (N₃⁻) anions. Carboxylate anions that contain 1-6 carbon atoms (C₁-C₆ carboxylate) and are illustrated by formate, acetate, propionate, butyrate, hexanoate, maleate, fumarate, oxalate, lactate, pyruvate, perfluoroalkyltrifluoroborate, hexafluorophosphate anion, bis(perfluoroethylsulfonyl)imide anion, pentafluorophenyl imide ions, bis((trifluoromethyl)sulfonyl)amide, bis(perfluoroalkylsufonyl)imide, tris(perfluoralkyl)trifuorophosphates, bis(trifluoromethylsulfonyl)imide, alkyl sulphonates, trihalides and mixed trihalides, alkylphosphates, alkylphosphonates, alkylthiophosphonates, and the like. Still other examples of anions that can be present in the disclosed compositions include, but are not limited to, sulfate, sulfites, phosphates, phosphites, nitrate, nitrites, hypochlorite, chlorite, perchlorate, bicarbonates, triflates, and the like, including mixtures thereof. Other examples of anions include, but are not limited to PF₆⁻ that is immiscible in water and BF₄⁻ that is miscible in water depending on the ratio of ionic liquid to water, system temperature, and alkyl chain length of cation. Other anions include triflate (TfO; CF₃SO₂⁻), nonaflate (NfO; CF₃(CF₂)₃SO₂⁻), bis(trifluoromethane)sulfonamide (Tf₂N or NTf₂; (CF₃SO₂)₂N⁻), trifluoroacetate (TA; CF₃CO₂⁻), and heptaflurorobutanoate (HB; CF₃(CF₂)₃SO₂⁻). Other types of ionic liquids include haloaluminates, such as chloroaluminate.

Other suitable anions include, but are not limited to, substituted and un-substituted imidazolates, 1,2,3-triazolates, 1,2,4-triazolates, benzimidazolates, and benz-1,2,3-triazolates, as shown below:

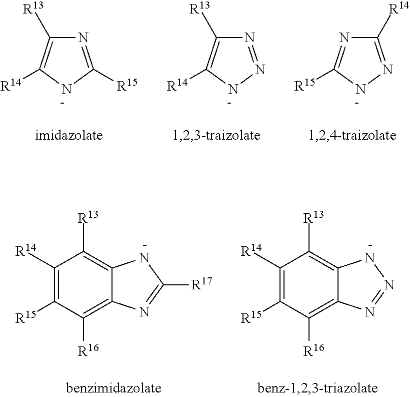

wherein R¹³, R¹⁴, R¹⁵, R¹⁶, R¹⁷, (R¹³⁻¹⁷), when present, are independently H, a substituted or unsubstituted linear, branched, or cyclic C₁-C₆ alkyl group, a substituted or unsubstituted linear, branched, or cyclic C₁-C₆ alkoxyalkyl group, a substituted or unsubstituted linear, branched, or cyclic C₁-C₆ alkoxy group, or energetic substituents like nitro, amino, cyano, azido, alkyl nitro, alkyl amino, alkyl cyano, alkyl azido, alkoxy nitro, alkoxy amino, alkoxy cyano, and alkoxy azido. Exemplary C₁-C₆ alkyl groups and C₁-C₄ alkyl groups include methyl, ethyl, propyl, iso-propyl, butyl, sec-butyl, iso-butyl, pentyl, iso-pentyl, hexyl, 2-ethylbutyl, 2-methylpentyl, and the like. Corresponding C₁-C₆ alkoxy groups contain the above C₁-C₆ alkyl group bonded to an oxygen atom that is also bonded to the cation ring. An alkoxyalkyl group contains an ether group bonded to an alkyl group, and here contains a total of up to six carbon atoms. It is to be noted that there are two isomeric 1,2,3-triazoles. In some examples, all R groups not required for anion formation can be H.

Further examples of suitable energetic anions are disclosed in Katritzky et al., “ILs Based on Energetic Azolate Anions,” Chem Eur J 12:4630, 2006, which is incorporated by reference herein at least for its teachings of energetic anions.

The disclosed ionic liquids can be liquid at or below a temperature of about 150° C., for example, at or below a temperature of about 100° C. and at or above a temperature of about minus 100° C. For example, N-alkylisoquinolinium and N-alkylquinolinium halide salts have melting points of less than about 150° C. The melting point of N-methylisoquinolinium chloride is 183° C., and N-ethylquinolinium iodide has a melting point of 158° C. In other examples, a contemplated ionic liquid is liquid (molten) at or below a temperature of about 120° C. and above a temperature of about minus 44° C. In some examples, a suitable ionic liquid can be liquid (molten) at a temperature of about minus 10° C. to about 100° C.

In one aspect, at least one ionic liquid comprises an optionally substituted imidazolium cation and at least one anion. For example, the optionally substituted imidazolium cation can be present as 1-alkyl 3-methylimidazolium, including 1-butyl 3-methylimidazolium chloride, 1-pentyl 3-methylimidazolium chloride, 1-hexyl 3-methyl imidazolium chloride, 1-heptyl 3-methylimidazolium chloride, 1-octyl 3-methylimidazolium chloride, 1-nonyl 3-methylimidazolium chloride, 1-decyl 3-methylimidazolium chloride, and 1-hexadecyl 3-methylimidazolium chloride.

An ionic liquid as disclosed herein can have a low vapor pressure and can optionally decompose prior to boiling. Exemplary liquefaction temperatures (i.e., melting points (MP) and glass transition temperatures (T_{g})) and decomposition temperatures for illustrative N,N-1,3-di-C₁-C₆-alkyl imidazolium ion-containing ionic liquids, wherein one of R¹ and R² is methyl, are shown in Table 1 below.

TABLE 1

| | Liquification | Decomposition | |
|---|---|---|---|
| | Temperature | Temperature | |
| Ionic Liquid | (° C.) | (° C.) | Citation* |
| [C₂mim] Cl | | 285 | a |
| [C₃mim] Cl | | 282 | a |
| [C₄mim] Cl | 41 | 254 | b |
| [C₆mim] Cl | −69 | 253 | |
| [C₈mim] Cl | −73 | 243 | |
| [C₂mim] I | | 303 | a |
| [C₄mim] I | −72 | 265 | b |
| [C₄mim] [PF₆] | 10 | 349 | b |
| [C₂mim] [PF₆] | 58-60 | 375 | c, a |
| [C₃mim] [PF₆] | 40 | 335 | a |
| [iC₃mim] [PF₆] | 102 | | a |
| [C₆mim] [PF₆] | −61 | 417 | d |
| [C₄mim] [BF₄] | −81 | 403, 360 | d,e |
| [C₂mim] [BF₄] | | 412 | a |
| [C₂mim] [C₂H₃O₂] | 45 | | c |
| [C₂mim] [C₂F₃O₂] | 14 | About 150 | f |

a) Ngo et al., Thermochim Acta 2000, 357: 97.
b) Fanniri et al., J Phys Chem 1984, 88: 2614.
c) Wilkes et al., Chem Commun 1992, 965.
d) Suarez et al., J Chem Phys 1998, 95: 1626.
e) Holbrey et al., J Chem Soc, Dalton Trans 1999, 2133.
f) Bonhote et al., Inorg Chem 1996, 35: 1168.

Two Dimensional Thermoelectric (TE) and Transition Metal Dichalcogenide Materials

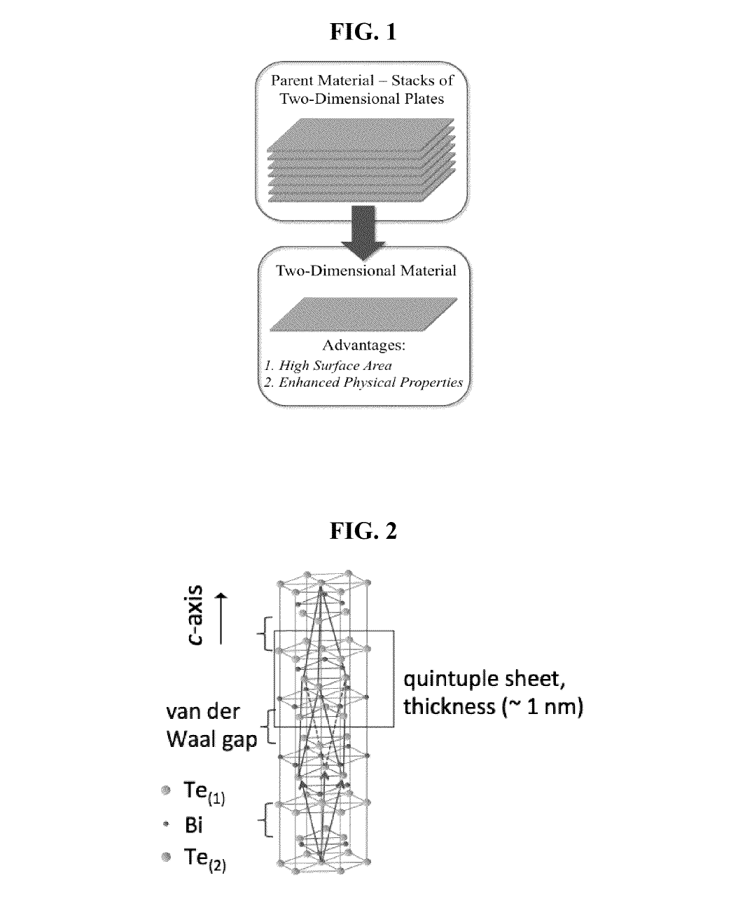

Two-dimensional (2D) or quasi 2D materials are essentially flat sheets that exhibit physical and chemical properties that can be superior to their three-dimensional (3D) bulk parent materials. Referring to FIG. 1, a schematic diagram of an exemplary process to form 2D material from 3D material is shown. The stacks of 2D plates in the parent 3D material at the top of the figure when separated to 2D material at the bottom of the figure provide high surface area as well as enhanced physical properties.

The heat-to-electricity conversion efficiency or refrigeration coefficient of performance of solid state thermoelectric devices is governed by the thermoelectric figure-of-merit, zT=S²σT/κ, where S is Seebeck coefficient, a is electrical conductivity, T is the absolute temperature, and K is thermal conductivity as discussed in F. D. Rosi, “Thermoelectricity and thermoelectric power generation,” Solid-State Electronics, vol. II, pp. 833-868, 1968.

Currently the materials with the highest thermoelectric figure of merit (zT=1.2) at room temperature are bismuth antimony telluride bulk alloys, disclosed by Bed Poudel et al., “High-Thermoelectric Performance of Nanostructured Bismuth Antimony Telluride Bulk Alloys,” Science, 2008, Vol. 320 no. 5876 pp. 634-638. Two-dimensional bismuth telluride quintuple sheets (QSs) have recently been predicted to possess a figure-of-merit (zT) of about 7.15 at room temperature in F. Zahid and R. Lake, “Thermoelectric properties of Bi₂Te₃ atomic quintuple thin films,” Applied Physics Letters, vol. 97, pp. 212102/1-212102/3. 2010. The high zT value may be due to the 2-D morphology of the V-VI based chalcogenide QSs (d˜1 nm); the thermal conductivity will be further reduced by phonon scattering effect as discussed in D. G. Cahill, W. K. Ford, et al., “Nanoscale thermal transport,” Journal of Applied Physics, vol. 93, pp. 793-818, 2003, and the Seebeck coefficient will be significantly enhanced by the quantum confinement effect as discussed in L. D. Hicks and M. S. Dresselhaus “Effect of quantum-well structures on the thermoelectric figure of merit,” Physical Review B, vol. 47, pp. 12727-12731, 1993. So far, the materials used in applications have all been in bulk form. By preparing these materials in quantum-well super lattice structures, it is possible to increase zT of certain materials. Specifically, layering has the potential to increase the figure of merit of an anisotropic material such as Bi₂Te₃, provided that the superlattice multilayers are made in a particular orientation.

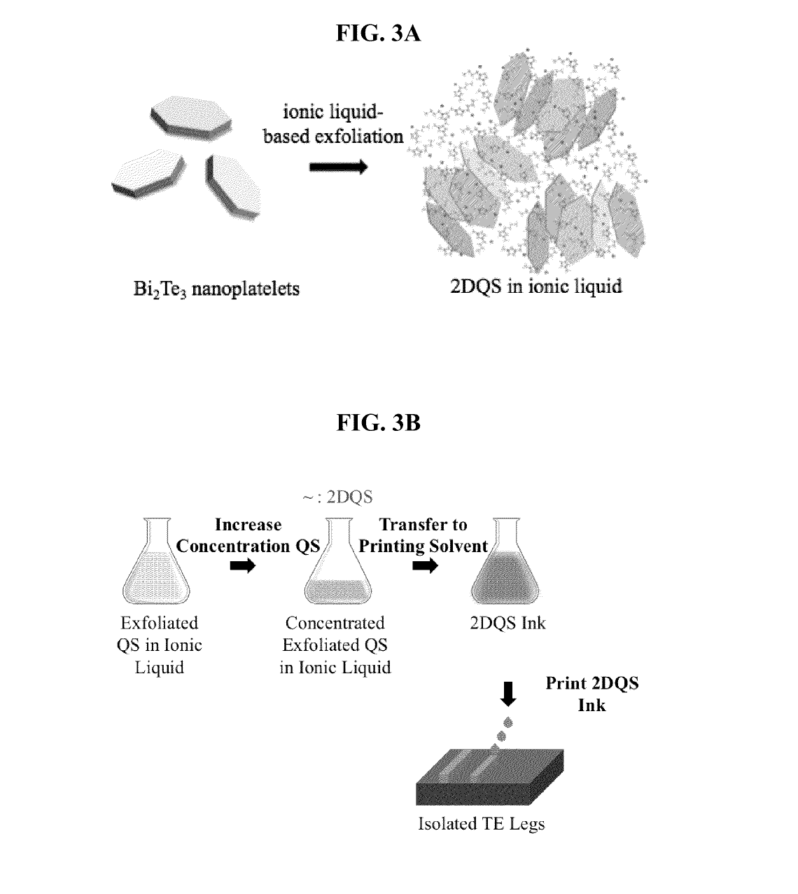

Referring to FIG. 2, a schematic diagram illustrating the crystal structure of Bi₂Te₃ is shown. A quintuple stack of Bi₂Te₃ is shown as stacks with a van der Waals gap between the neighboring quintuple stacks QSs (i.e., between adjacent Te₍₁₎ layers, as shown in FIG. 2). Because the nature of the bonding between neighboring QSs is a weak van der Waals interaction, it is possible to exfoliate Bi₂Te₃ nanoplatelets into two-dimensional quintuple sheets (2DQSs). Although a process of graphite exfoliation to produce graphene sheets in ionic liquids has been reported in U.S. Patent Application Publication No. 20110319554 to Frazier et al. entitled “Exfoliation of graphite using ionic liquids,” the disclosure herein provide the unique exfoliated 2DQSs of bismuth telluride based on its quintuple stack structures, as discussed above. The methods disclosed herein are suitable for forming 2DQSs of bismuth telluride and other related chalcogenides, including Sb₂Te₃, by exfoliating nanoplatelets using ionic liquids. A schematic diagram of the ionic liquid based exfoliation of bismuth telluride is illustrated in FIG. 3A.

Printing thermoelectric (TE) devices have recently been investigated because of the feasibility to meet varied fabrication requirements for different applications, as discussed for example in D. Madan, A. Chen et al., “Dispenser printed composite thermoelectric thick films for thermoelectric generator applications,” Journal of Applied Physics, vol. 109, pp. 034904•6, 2011 and in A. Chen, D. Madan el al., “Dispenser-printed planar thick film thermoelectric energy generators,” Journal of Micromechanics and Microengineering, vol. 21, p. 104006, 2011. However, the larger particle size of V-VI based chalcogenides used in the reported ink eliminates the possibility of taking advantage of quantum confinement as well as topological surface states that two-dimensional quintuple sheets offer and therefore limits the overall device efficiency. To overcome this challenge, 2DQS inks disclosed herein sustain the two-dimensional nature of the quintuple sheets that can help attain a suitable TE figure of merit.

Slack has proposed in the CRC Handbook of Thermoelectrics, ed. DM Rowe, Boca Raton, Fla.: CRC Press (1995), that in order to optimize the figure of merit, phonons, which are responsible for thermal conductivity must experience the material as they would in a glass (experiencing a high degree of phonon scattering—lowering thermal conductivity) while electrons must experience it as a crystal (experiencing very little scattering-maintaining electrical conductivity). The figure of merit can be improved through the independent adjustment of these properties. Candidates of thermoelectric materials in addition to bismuth telluride and antimony telluride include, for example, telluride alloys (or chalcogenides) that can be represented by the general formula Bi₍₂₋ₓ₎SbₓTe_{(3-y)}Se_{y}, where 0≦x≦2, and 0≦y≦3, for example Bi₂Se₃, Sb₂Te₃, Sb₂Se₃, Bi₂Te₂₇Se_{0.3}, Bi_{0.5}Sb_{1.5}Te₃, Bi₂Te_{1.4}Se_{0.6}, Bi_{0.4}Sb_{1.6}Te₃, and Bi₂Te_{2.85}Se_{0.15}, that have layered structures.

Additional layered dichalcogenides are disclosed in Nature Chemistry 5, 263-275 (2013) doi:10.1038/nchem.1589, the teaching of the chalcogenides including dichalcogenides are incorporated herein by reference. For instance, the ionic liquid-based exfoliation disclosed herein can be compatible for exfoliating transition metal dichalcogenides represented by formula MX₂, where M can be Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), Palladium (Pd), or Platinum (Pt), and X can be Sulfur (S), Selenium (Se), or Tellurium (Te). The exfoliated transition metal dichalcogenides (MX₂) can be applied in areas, such as electronics, opto-electronics, photovoltaics, sensors, Li-ion batteries, supercapacitors, etc.

### Methods

Disclosed herein are methods for exfoliating a thermoelectric material or a transition metal dichalcogenide, thereby providing an exfoliated thermoelectric material or an exfoliated transition metal dichalcogenide. In some examples, the thermoelectric material can comprise bismuth telluride, and the exfoliated thermoelectric material can comprise exfoliated bismuth telluride. In some examples, bismuth telluride can be exfoliated using any of the compositions disclosed herein. While not wishing to be bound by theory, it is believed that the ionic liquid of the disclosed compositions can disrupt the van der Waals interaction between the quintuple sheets of bismuth telluride, thereby allowing the formation of an at least partially homogenous solution of bismuth telluride quintuple sheets (QS) and ionic liquid, and, subsequent exfoliation of bismuth telluride to provide exfoliated bismuth telluride, suspended in the solution.

In some examples, the method for making an exfoliated thermoelectric material or an exfoliated transition metal dichalcogenide comprises providing a mixture comprising a thermoelectric material or a transition metal dichalcogenide and at least one ionic liquid; substantially homogenizing the mixture by imparting sufficient energy to separate the quintuple sheets within the thermoelectric material or transition metal dichalcogenide, thereby making the exfoliated thermoelectric material QS or the exfoliated transition metal dichalcogenide QS. In some examples, the substantially homogenized mixture can subsequently be substantially de-homogenized, such as, for example, by centrifugation, to enable the recovery and isolation of the exfoliated thermoelectric material QS or the exfoliated transition metal dichalcogenide QS, if present. In some examples, the mixture can be diluted, e.g., with water, prior to substantially de-homogenizing the mixture. In some examples, the exfoliated thermoelectric material QS or the exfoliated transition metal dichalcogenide QS can be recovered and/or isolated from the de-homogenized mixture by known methods, such as, for example, by filtration and/or flocculation.

In some examples, substantially homogenizing the mixture comprises imparting energy to the mixture. Such energy can, for example, be in the form of ultrasonic energy, electrical energy, mechanical energy, thermal energy, and the like, or a combination thereof. In some examples, imparting energy to the mixture can be accomplished by agitating the mixture. Any appropriate energy source can be used, such as, for example, ultrasonic energy (i.e., through sonication). In some examples, substantially homogenizing the mixture comprises agitating (e.g., sonicating) the mixture for a period of time sufficient to substantially homogenize the mixture. The period of time can vary depending on sample size and/or concentration, among other factors. In some examples, the period of time can be on the order of hours, such as for, example, from 1 to 10 hours. Also disclosed herein are the exfoliated thermoelectric material QS and the exfoliated transition metal dichalcogenide QS made by any of the methods disclosed herein.

Also disclosed herein are methods for making a printable ink comprising exfoliated two dimensional sheets of a thermoelectric material or a transition metal dichalcogenide. The method can comprise mixing a composition comprising exfoliated two dimensional sheets of the thermoelectric material or the transition metal dichalcogenide and at least one ionic liquid with a printing solvent. The composition comprising exfoliated two dimensional sheets of the thermoelectric material or the transition metal dichalcogenide and at least one ionic liquid can comprise any of the compositions described herein, or be obtained by any of the methods described herein. In some examples, the composition comprising exfoliated two dimensional sheets of the thermoelectric material or the transition metal dichalcogenide and at least one ionic liquid can be concentrated prior to mixing with the printable solvent, for example through filtration, centrifugation, flocculation, or combinations thereof.

In some examples, the methods disclosed herein relate to preparing a printable ink comprising exfoliated bismuth telluride QS. Such a printable ink can be used in any appropriate application, such as, for example, printed electronics in thermoelectric applications. In some examples, the method for making a printable ink comprising exfoliated bismuth telluride QS comprises: providing a mixture comprising exfoliated bismuth telluride QS and at least one ionic liquid; increasing the concentration of the bismuth telluride QS to form concentrated exfoliated QS in ionic liquid; and mixing the concentrated exfoliated QS in the ionic liquid with a printing solvent to provide a printable ink that comprises exfoliated bismuth telluride.

Traditional inks for printing thermoelectric legs (micro-size lines) use volatile organic solvents such as ethylene glycol or tetradecane, with optional polymer binder systems such as epoxy/hardener or polystyrene. Epoxy/hardener systems used in traditional thermoelectric ink have limited success and have been limited to large particles. The thermoelectric ink disclosed herein reduces bismuth telluride QS agglomeration while taking advantage of the unique characteristics of the bismuth telluride QSs. The disclosed 2DQSs can also be mixed with optional conducting polymers, such as polyacetylene, polyaniline, poly(3,4-ethylenedioxythiophene) (PEDOT), and poly(3-hexylthiophene-2,5-diyl) (P3HT). Referring to FIG. 3B, a schematic diagram illustrating a method of forming a printable ink using bismuth telluride QS in ionic liquid is shown. Printable ink comprising bismuth telluride QS with or without ionic liquid is printed on substrate sheets and cured. Suitable substrate materials include polyethylene, polyimide, transparent conductive polyester, paper, glass, and silicon. The exfoliated thermoelectric material can be concentration through filtration, centrifugation, and/or flocculation before it is further processed in a process such as ink making.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

All chemicals used were of analytical grade, purchased from Sigma-Aldrich (Milwaukee, Wis.), and used without further purification unless otherwise noted.

### Example 1

### Exfoliation of Synthetic Bismuth Telluride Nanoplatelets

Approximately 0.01 wt % solvothermal synthesized bismuth telluride nanoplatelets was added to an ionic liquid, such as 1-butyl 3-methylimidazolium chloride (bmimCl), 1-butyl 3-methylimidazolium bis(trifluoromethane)sulfonimide([Bmim][NTf₂]), 1-ethyl-3-methylimidazolium bis(trifluoromethane)sulfonimide([Emim][NTf₂]), or 1-ethyl-3-methylimidazolium acetate ([Emim][OAc]) to form a reaction mixture. While bmimCl, [Bmim][NTf₂], and [Emim][NTf₂] provided good exfoliation, the exfoliation by [Emim][OAc] was poor. Results from bmimCl are discussed below as an example.

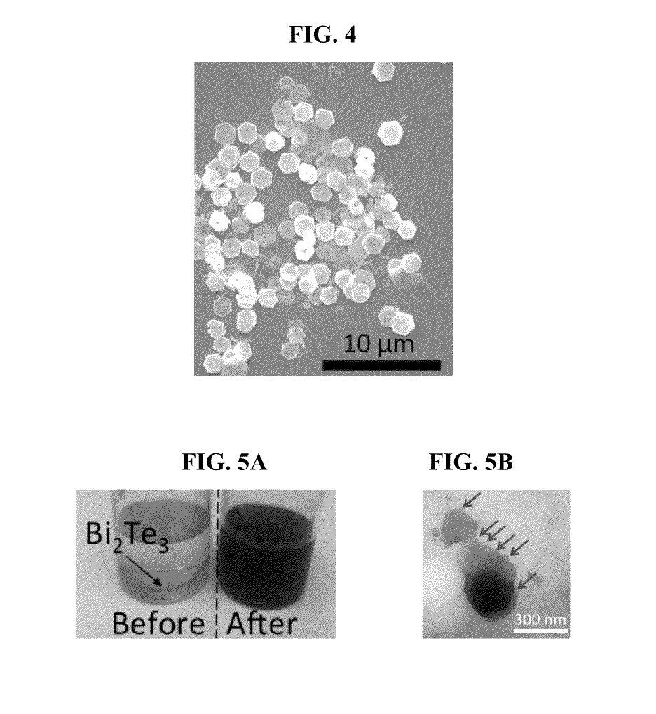

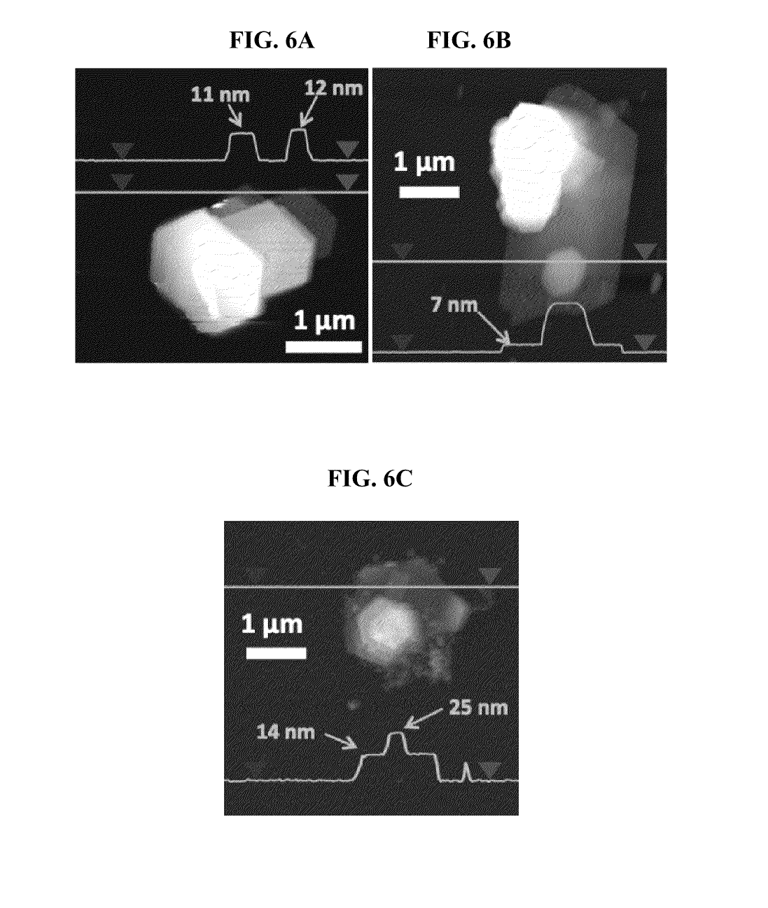

In FIG. 4, the scanning electron microscopy (SEM) image of solvothermal synthesized bismuth telluride nanoplatelets reveals that the Bi₂Te₃ nanoplatelets have size dimensions in the micrometer range. The synthesis of these Bi₂Te₃ nanoplatelets used as a raw material of this ionic liquid exfoliation is disclosed in Lingling Guo et al., “Selective adsorption of bismuth telluride nanoplatelets through electrostatic attraction,” Phys. Chem. Chem. Phys., 2014, 16, 11297-11302. The bismuth telluride nanoplatelets appeared to settle at the bottom of the reaction vial in the reaction mixture, as shown in the left photo of FIG. 5A, while bmimCl remained clear and almost colorless. The reaction mixture was sonicated for ˜1 hr to form a homogeneous dark solution, shown in the right photo of FIG. 5A. The exfoliation of bismuth telluride QS is evidenced by the homogeneous dark solution shown in FIG. 5A. Part of the resulting composite solution was diluted with deionized water and centrifuged. Transmission electron microscopy (TEM) was used to image the resulting particles and the micrograph is shown in FIG. 5B, with six arrows pointing to six flakes of exfoliated bismuth telluride QSs or stacks of a few QSs. The exfoliated bismuth telluride QS in the remaining composite solution remained suspended for more than 6 months. FIG. 6A-6C are the atomic force microscopy (AFM) images of the three randomly-selected exfoliated bismuth telluride nanosheets. The thickness of exfoliated nanosheets is clearly thinner than that of the initial nanoplatelets (˜100 nm).

### Example 2

### Concentration of Exfoliated Bismuth Telluride Nanosheets

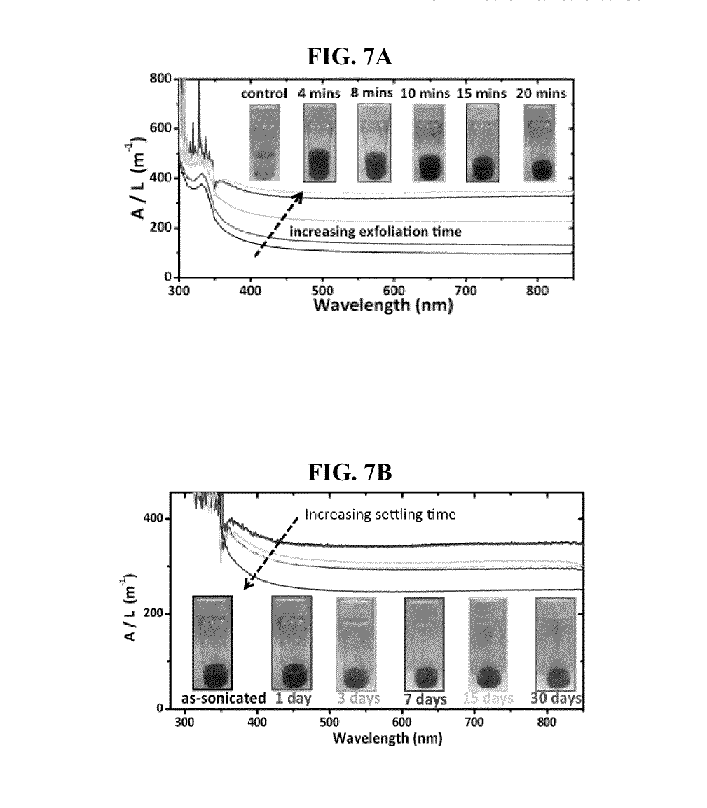

UV-Vis absorption can be used to obtain the dispersion concentration of exfoliated bismuth telluride through the Lambert-Beer Law: A/l=εC. Since the Lambert-Beer Law is a consideration solely for material absorption (A), it is necessary to obtain the ultimate exfoliation state with uniform nanosheet morphology, and therefore, the scattering background can be reasonably subtracted. To quantify the dispersion concentrations (C), centrifugation was performed to obtain the dispersions in the supernatant containing only finely-exfoliated 2D nanosheets. The dispersion concentration using the sedimentation function: C=C₀+C₂e^{-t/t}^{₁}+C₂e^{-t/t}^{₂}, where C₀ is the initial concentration, and C₁ and C₂ represent sedimentations from aggregations of exfoliated nanosheets and un-exfoliated big particles, respectively. As an example, FIG. 7A displays the “exfoliation time”-dependent UV-Vis spectra and the photographs of the reaction solution showing increased absorption with increasing exfoliation time from 4 mins to 20 mins. The thickness of the exfoliated nanosheets is 7-14 nm (as shown in FIG. 6A-C), which suggests that the thickness can be further reduced by IL design, exfoliation time, and sonication power. FIG. 7B displays “settling time”-dependent UV-Vis spectra and the photographs of the solution showing a slow decrease of absorption with increasing settling time from 1 day to 30 days. Interestingly, the color of the dispersion remained dark over 30 days, which implies that the nanosheet dispersion concentration was not reduced much within a month and the dispersion is very stable.

### Example 3

### Exfoliation of Synthetic Bismuth Telluride Commercial Powder

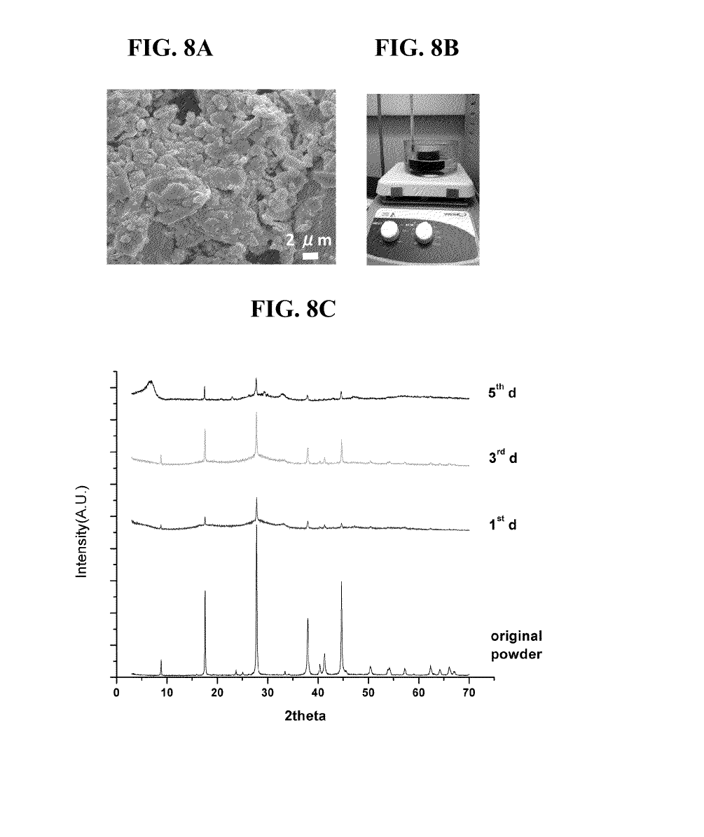

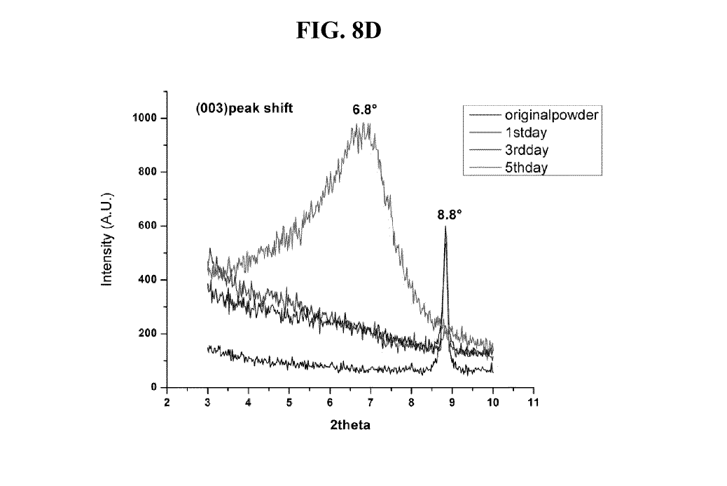

A more general method is to exfoliate commercial thermoelectric chalcogenide powders by a simple solvothermal reaction. In this example, commercial powder of bismuth telluride was first ground before the reaction. FIG. 8A is the SEM image of the ground powder, indicating there is a wide range of particle size, from 100 nm to 20 μm. The solvothermal reaction setup is shown in FIG. 8B. Bismuth telluride powder and bmimCl were mixed in an amber jar by a stirring bar at 80° C. for 30 minutes. The weight ratio of bmimCl to bismuth telluride powder was 50 to 1. The mixture was kept in a mineral oil bath at a temperature of 120° C. for a varied amount of time to induce intercalation of bmimCl in bismuth telluride.

FIG. 8C and FIG. 8D displays the X-ray Diffraction (XRD) spectra for 120° C. treated products with different durations. It can be seen that the 2θ position of the (003) peak for the 5^{th}-day product shifted from a sharp peak at 8.8° (the original powder) to a wide peak at 6.8° (reacted powder). This indicates that intercalation occurred and the van der Waals gaps were increased to some extent.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

What is claimed is:

1. A method for making exfoliated two-dimensional sheets of a thermoelectric material or a transition metal dichalcogenide, the method comprising:
homogenizing a mixture comprising the thermoelectric material or the transition metal dichalcogenide and at least one ionic liquid to form a homogenous suspension of the two dimensional sheets of the thermoelectric material or the transition metal dichalcogenide in the ionic liquid.

2. The method of claim 1, further comprising extracting the exfoliated two dimensional sheets of the thermoelectric material or the transition metal dichalcogenide from the mixture.

3. The method of claim 1, wherein substantially homogenizing the mixture comprises imparting energy to the mixture.

4. The method of claim 1, wherein substantially homogenizing the mixture comprises sonicating the mixture for a period of time sufficient to exfoliate the thermoelectric material or the transition metal dichalcogenide to form the two dimensional sheets of the thermoelectric material or the transition metal dichalcogenide and substantially homogenize the mixture.

5. The method of claim 1, wherein the two dimensional sheets of the thermoelectric material or the transition metal dichalcogenide are two-dimensional quintuple sheets or a few layer stacks of quintuple sheets.

6. The method of claim 1, wherein the at least one ionic liquid comprises an optionally substituted cation that comprises a stoichiometric or non-stoichiometric mixture of heterocyclic, quaternary ammonium, or quaternary phosphonium based cation paired with either a halide, pseudohalide, azolate, carboxylate, hexafluorophosphate, or bis(trifluoromethane)sulfonamide anion.

7. The method of claim 1, wherein the at least one ionic liquid possesses an accessible liquid range and comprises an azolium cation paired with a halide, pseudohalide, azolate, carboxylate, hexafluorophosphate, or bis(trifluoromethane)sulfonamide anion.

8. The method of claim 1, wherein the at least one ionic liquid possesses an accessible liquid range and comprises an optionally substituted imidazolium cation and at least one anion.

9. The method of claim 8, wherein the ionic liquid is 1-butyl 3-methylimidazolium chloride (bmimCl), 1-butyl 3-methylimidazolium bis(trifluoromethane)sulfonimide([Bmim][NTf₂]), or 1-ethyl-3-methylimidazolium bis(trifluoromethane)sulfonimide([Emim][NTf₂]).

10. The method of claim 1, wherein the thermoelectric material is bismuth telluride and/or antimony telluride and the two dimensional sheets are quintuple sheets or a few layer stacks of quintuple sheets of bismuth telluride and/or antimony telluride.

11. The method of claim 1, wherein the thermoelectric material is a thermoelectric chalcogenide represented by the formula Bi₍₂₋ₓ₎SbₓTe_{(3-y)}Se_{y}, where 0≦x≦2, and 0≦y≦3.

12. The method of claim 11, wherein the thermoelectric material is Bi₂Te₃, Bi₂Se₃, Sb₂Te₃, Sb₂Se₃, Bi₂Te_{2.7}Se_{0.3}, Bi_{0.5}Sb_{1.5}Te₃, Bi₂Te_{1.4}Se_{0.6}, Bi_{0.4}Sb_{1.6}Te₃, or Bi₂Te_{2.85}Se_{0.15}.

13. The method of claim 1, wherein the transition metal dichalcogenide is represented by formula MX₂, where M is Titanium (Ti), Zirconium (Zr), Hafnium (Hf), Vanadium (V), Niobium (Nb), Tantalum (Ta), Molybdenum (Mo), Tungsten (W), Technetium (Tc), Rhenium (Re), Cobalt (Co), Rhodium (Rh), Iridium (Ir), Nickel (Ni), Palladium (Pd), or Platinum (Pt); and X is Sulfur (S), Selenium (Se), or Tellurium (Te).

14. A composition comprising the exfoliated two-dimensional sheets of a thermoelectric material or a transition metal dichalcogenide homogenously suspended in at least one ionic liquid made by the method of claim 1.

15. The composition of claim 14, comprising from about 0.01% to about 1% of the thermoelectric material or the transition metal dichalcogenide by weight of the total composition.

16. The composition of claim 14, comprising from about 0.01% to about 0.5% of the thermoelectric material or the transition metal dichalcogenide by weight of the total composition.

17. A method for making a printable ink comprising exfoliated two dimensional sheets of a thermoelectric material or a transitional metal dichalcogenide, the method comprising: mixing a concentrated mixture that comprises exfoliated two dimensional sheets of the thermoelectric material or the transition metal dichalcogenide and at least one ionic liquid with a printing solvent

18. The method of claim 17, further comprising mixing the concentrated mixture and the printing solvent with an additive.

19. The method of claim 18, wherein the additive is a conducting polymer selected from the group consisting of polyacetylene, polyaniline, poly(3,4-ethylenedioxythiophene), poly(3-hexylthiophene-2,5-diyl), or combination thereof.

20. The method of claim 17, further comprising making the concentrated mixture through filtration, centrifugation, and/or flocculation of a homogenous mixture of two dimensional sheets of the thermoelectric material or transition metal dichalcogenide and at least one ionic liquid made by the method of claim 1.

21. A printable ink made by the method of claim 17.

22. A method comprising printing the printable ink of claim 21 on a substrate to form a device.

23. The method of claim 22, wherein the substrate is polyethylene, polyimide, transparent conductive polyester, paper, glass, or silicon.

24. The method of claim 22, wherein the device is an electronic device, a thermoelectric device, an opto-electronic device, a photovoltaic device, a sensor, a Li-ion battery or a supercapacitor.
